(19) United States
(12) Patent Application Publication
(10) Pub. No.: US 2023/0180620 A1
(43) Pub. Date: Jun. 8, 2023

(54) SEMICONDUCTOR DEVICE AND METHOD FOR FABRICATING THE SAME

(71) Applicants: SK hynix Inc., Gyeonggi-do (KR); Kioxia Corporation, Tokyo (JP)

(72) Inventors: Ku Youl JUNG, Gyeonggi-do (KR); Jung Hyeok KWAK, Gyeonggi-do (KR); Jin Won JUNG, Gyeonggi-do (KR); Young Min EEH, Tokyo (JP)

(21) Appl. No.: 17/969,233

(22) Filed: Oct. 19, 2022

(30) Foreign Application Priority Data
Dec. 7, 2021 (KR) 10-2021-0174229

(51) Int. Cl. H01L 43/12; H01L 27/22; H01L 43/02

(52) U.S. Cl. CPC H01L 43/12; H01L 27/226; H01L 43/02

(57) ABSTRACT

A method for fabricating a semiconductor device may include: forming a first magnetic layer over a substrate; forming a tunnel barrier layer over the first magnetic layer by repeatedly performing a unit process of forming a material layer and performing a rapid thermal annealing (RTA) process on the material layer; and forming a second magnetic layer over the tunnel barrier layer.

### CROSS-REFERENCE TO RELATED APPLICATIONS

The present application claims priority to Korean Patent Application No. 10-2021-0174229, filed on Dec. 7, 2021, which is incorporated herein by reference in its entirety.

### BACKGROUND

### 1. Field

Various embodiments of the present invention relate to memory circuits or devices and their applications in electronic devices or systems.

### 2. Description of the Related Art

The recent trend toward miniaturization, low power consumption, high performance, and multi-functionality in the electrical and electronics industry has compelled the semiconductor manufacturers to focus on high-performance, high capacity semiconductor devices. Examples of such high-performance, high capacity semiconductor devices include memory devices that can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), and an electronic fuse (E-fuse).

### SUMMARY

Various embodiments of the present invention include memory circuits or devices and their applications in semiconductor devices or systems and various implementations of a semiconductor device that can improve the performance of a semiconductor device.

In accordance with one embodiment, a semiconductor device may include: a magnetic tunnel junction (MTJ) structure having a free layer having a variable magnetization direction, a pinned layer having a fixed magnetization direction, and a tunnel barrier layer which is interposed between the free layer and the pinned layer and which includes a plurality of material layers having a thickness of two monolayers or less and with each material layer individually crystallized.

In accordance with another embodiment, a method for fabricating a semiconductor device may include: forming a first magnetic layer over a substrate; forming a tunnel barrier layer over the first magnetic layer by repeatedly performing a unit process of forming a material layer and performing a rapid thermal annealing (RTA) process on the material layer; and forming a second magnetic layer over the tunnel barrier layer.

### BRIEF DESCRIPTION OF THE DRAWINGS

FIGS. 1A and 1B are cross-sectional views illustrating a method for forming a variable resistance element in accordance with a comparative example.

FIG. 2 is a cross-sectional view illustrating an example of a variable resistance element in accordance with one embodiment of the present invention.

FIGS. 3A to 3E are cross-sectional views illustrating an example of a method for forming a semiconductor device in accordance with another embodiment of the present invention.

FIGS. 4A to 4F are cross-sectional views illustrating an example of a method for forming a tunnel barrier layer in accordance with still another embodiment of the present invention.

FIG. 5 is a graph illustrating magnetoresistance (MR) and exchange coupling field (Hex) characteristics of variable resistance elements in accordance with yet another embodiment of the present invention and comparative examples.

FIG. 6 is a cross-sectional view illustrating an example of a semiconductor device and a method for forming the same in accordance with another embodiment of the present invention.

FIG. 7 is a cross-sectional view illustrating another example of a semiconductor device and a method for forming the same in accordance with still another embodiment of the present invention.

### DETAILED DESCRIPTION

Various embodiments described herein may be described with reference to cross-sectional views, plane views and block diagrams, which are ideal schematic views of the semiconductor device according to specific embodiments of the present invention. It is noted that the structures of the drawings may be modified by fabricating techniques and/or tolerances. The present invention is not limited to the described embodiments and the specific structures shown in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the invention.

Prior to explaining embodiments of the present invention, a comparative example will be described.

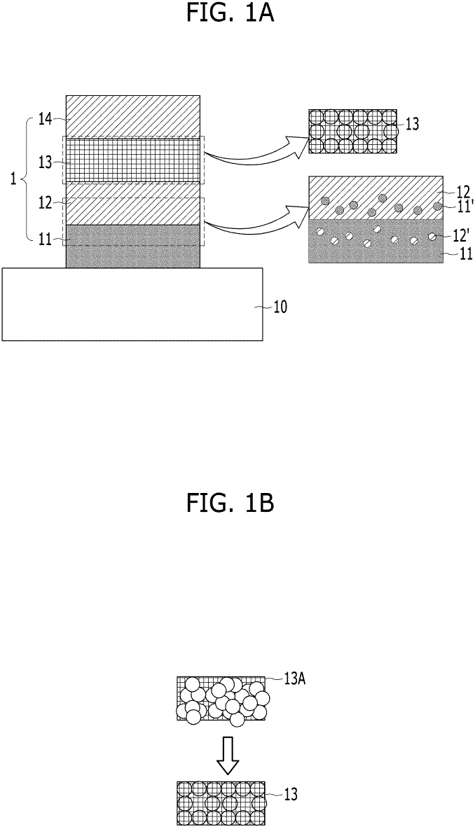

FIGS. 1A and 1B are cross-sectional views illustrating a method for forming a variable resistance element in accordance with a comparative example.

Referring to FIG. 1A, a variable resistance element 1 in accordance with a comparative example may be an MRAM including an MTJ structure including a free layer 12, a tunnel barrier layer 13 and a pinned layer 14. One type of the MRAM is a spin torque transfer MRAM (STT-MRAM) including the MTJ structure, and a change of a magnetization direction of the free layer 12 is based on a spin transfer torque.

The free layer 12 may have a variable magnetization direction that causes the MTJ structure to have a variable resistance value. The free layer 12 may also be referred as a storage layer.

The pinned layer 14 may have a pinned magnetization direction, which remains unchanged while the magnetization direction of the free layer 12 changes. For this reason, the pinned layer 14 may be referred to as a reference layer.

Depending on a voltage or current applied to the variable resistance element 1, the magnetization direction of the free layer 12 may be changed by spin torque transfer. When the magnetization directions of the free layer 12 and the pinned layer 14 are parallel to each other, the variable resistance element 1 may be in a low resistance state, and this may indicate a digital data bit “0.” Conversely, when the magnetization directions of the free layer 12 and the pinned layer 14 are anti-parallel to each other, the variable resistance element 1 may be in a high resistance state, and this may indicate a digital data bit “1.” That is, the variable resistance element 1 may function as a memory cell to store a digital data bit based on the orientation of the free layer 12.

The tunnel barrier layer 13 may allow the tunneling of electrons to change the magnetization direction of the free layer 12. The tunnel barrier layer 13 may include an insulating oxide.

The variable resistance element 1 may further include various layers for improving characteristics of the MTJ structure. For example, the variable resistance element 1 may further include a buffer layer 11 disposed below the MTJ structure.

The buffer layer 11 may be disposed below the free layer 12 to improve perpendicular magnetic crystalline anisotropy of the free layer 12. Alternatively, the buffer layer 11 may facilitate crystal growth of layers disposed over the buffer layer 11. Alternatively, the buffer layer 11 may resolve the lattice constant mismatch between a bottom electrode and the layers disposed over the buffer layer 11.

The switching of the magnetization direction of the free layer 12 may be affected by a tunnel magnetoresistance (TMR). An MRAM cell having a high TMR may have a high read signal, which may increase the read speed of the MRAM cell during operation.

In general, an MTJ having a uniform crystal structure without defects in the microstructure of the layers included in the MTJ may have a higher TMR than an MTJ having structural defects. Therefore, the TMR may be increased by maximizing coherent tunneling through crystal growth of the tunnel barrier layer 13 and the ferromagnetic layers 12 and 14 disposed on and below the tunnel barrier layer 13.

Thus, the free layer 12, the tunnel barrier layer 13 and the pinned layer 14 may be crystalized by applying a thermal treatment on material layers for forming the free layer 12, the tunnel barrier layer 13 and the pinned layer 14. The thermal treatment for crystal growth of the free layer 12, the tunnel barrier layer 13 and the pinned layer 14 may be performed at a high temperature for a long time. The thermal treatment may be performed in a furnace. The total time for the thermal treatment in the furnace including the thermal treatment itself at a crystallization temperature for several tens of minutes and the heating process and the cooling process before and after the thermal treatment may take several hours. When such high-temperature and long-time thermal treatment is performed, the total thermal budget applied to the MTJ is very high, and thus the layers included in the MTJ as well as the layers located below the MTJ may be affected.

As shown in FIG. 1A, intermixing and diffusion of metal atoms included in the buffer layer 11 and the free layer 12 may occur between the buffer layer 11 and the free layer 12. Accordingly, particles 12′ including metal atoms derived from the free layer 12 may be present in the buffer layer 11 adjacent to an interface between the buffer layer 11 and the free layer 12 and particles 11′ including metal atoms derived from the buffer layer 11 may be present in the free layer 12 adjacent to the interface between the buffer layer 11 and the free layer 12. The intermixing and diffusion of the metal atoms between the layers included in the variable resistance element 1 may deteriorate characteristics of the variable resistance element 1.

In addition, defects may occur in an internal structure of the tunnel barrier layer 13 crystallized by the thermal treatment at a high temperature for a long time. As shown in FIG. 1A, the tunnel barrier layer 13 may have a non-uniform crystal structure with crystallization defects generated by the thermal treatment at a high temperature for a long time.

Issues in the crystal growth of the tunnel barrier layer 13 caused by the high-temperature and long-term thermal treatment will be described again with respect to FIG. 1B.

Referring to FIG. 1B, since the tunnel barrier layer 13 is formed by forming a material layer 13A as a single layer and then crystallizing the material layer 13A by the high-temperature and long-term thermal treatment, the crystal growth and orientation of the tunnel barrier layer 13 may become non-uniform. Therefore, the tunnel barrier layer 13 has crystallization defects and a non-uniform crystal structure, thereby deteriorating a TMR characteristic of the variable resistance element 1.

Accordingly, embodiments of the present invention may provide a semiconductor device and a method for fabricating the same, which can improve crystallinity of the tunnel barrier layer of the MTJ and reduce or minimize intermixing and diffusion between the layers, thereby improving characteristics of the variable resistance element.

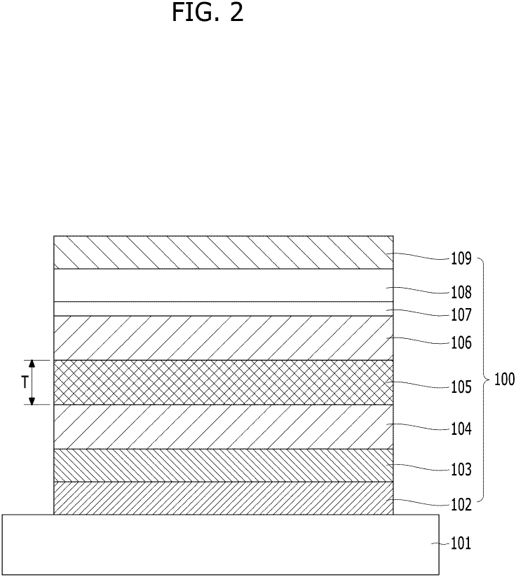

FIG. 2 is a cross-sectional view illustrating an example of a variable resistance element in accordance with one embodiment of the present invention.

Referring to FIG. 2, a variable resistance element 100 may include an MTJ structure including a free layer 104 having a variable magnetization direction, a pinned layer 106 having a pinned magnetization direction and a tunnel barrier layer 105 interposed between the free layer 104 and the pinned layer 106.

The free layer 104 may have one of different magnetization directions or one of different spin directions of electrons to switch the polarity of the free layer 104 in the MTJ structure, resulting in changes in resistance value. In some implementations, the polarity of the free layer 104 is changed or flipped upon application of a voltage or current signal (e.g., a driving current above a certain threshold) to the MTJ structure. With the polarity changes of the free layer 104, the free layer 104 and the pinned layer 106 have different magnetization directions or different spin directions of electron, which allows the variable resistance element 100 to store different data or represent different data bits. The free layer 104 may also be referred as a storage layer. The magnetization direction of the free layer 104 may be substantially perpendicular to a surface of the free layer 104, the tunnel barrier layer 105 and the pinned layer 106. In other words, the magnetization direction of the free layer 104 may be substantially parallel to stacking directions of the free layer 104, the tunnel barrier layer 105 and the pinned layer 106. Therefore, the magnetization direction of the free layer 104 may be changed between a downward direction and an upward direction. The change in the magnetization direction of the free layer 104 may be induced by a spin transfer torque generated by an applied current or voltage.

The free layer 104 may have a single-layer or multilayer structure including a ferromagnetic material. For example, the free layer 104 may include an alloy based on at least one of Fe, Ni or Co, for example, an Fe—Pt alloy, an Fe—Pd alloy, a Co—Pd alloy, a Co-Pt alloy, an Fe—Ni—Pt alloy, a Co—Fe—Pt alloy, a Co—Ni—Pt alloy, or a Co—Fe—B alloy, or others, or may include a stack of metals, such as Co/Pt, or Co/Pd, or others.

The tunnel barrier layer 105 may allow the tunneling of electrons in both data reading and data writing operations. In a write operation for storing new data, a high write current may be directed through the tunnel barrier layer 105 to change the magnetization direction of the free layer 104 and thus to change the resistance state of the MTJ for writing a new data bit. In a reading operation, a low reading current may be directed through the tunnel barrier layer 105 without changing the magnetization direction of the free layer 104 to measure the existing resistance state of the MTJ under the existing magnetization direction of the free layer 104 to read the stored data bit in the MTJ. The tunnel barrier layer 105 may include an insulating oxide such as for example MgO, CaO, SrO, TiO, VO, NbO, Al₂O₃, TiO₂, Ta₂O₅, RuO₂, B₂O₃, or the like.

The tunnel barrier layer 105 may ensure a low resistance area product (RA) value and a high TMR characteristic in order to improve a characteristic of the variable resistance element 100.

The TMR may be expressed as a difference between the electrical resistance in the anti-parallel state (Rap) and the electrical resistance in the parallel state (Rp) with respect to the electrical resistance in the parallel state (Rp). The MTJ with a uniform crystal structure without structural defects may have a higher TMR than an MTJ with structural defects. Since a higher TMR generates a larger signal difference between the on/off states of the cell, a high TMR for a stable reading operation is preferred. The electrical resistance of the magnetic memory device may vary depending on the thickness T of the tunnel barrier layer 105.

The RA value is a resistance value normalized by a unit area and may be expressed as the product of the resistance and the area. The RA value may be an important factor in determining a signal to noise ratio and a resistive-capacitive (RC) time constant in the magnetic memory device. The RA value may be an indication of the voltage (e.g., a threshold switching voltage) used to reverse the magnetization direction of the free layer 104. As the RA value increases, the cell may use a higher threshold switching voltage, thereby deteriorating performance of the cell and reducing a lifetime of the cell. It is possible to reduce the RA value by decreasing the thickness T of the tunnel barrier layer 105. However, when the thickness T of the tunnel barrier layer 105 is decreased, the TMR value may be also decreased. Therefore, both a low RA value and a high TMR characteristic cannot be achieved only by adjusting the thickness T of the tunnel barrier layer 105.

In accordance with one embodiments of the present invention, structural defects can be eliminated or minimized in the crystal structure of the tunnel barrier layer 105 in order to maintain a low RA value and increase the TMR characteristic.

In various embodiments, the tunnel barrier layer 105 may have a uniform crystal structure in which defects are not present or are minimized. In some embodiments, the tunnel barrier layer 105 may have a bcc (001) crystal structure. In some embodiments, the tunnel barrier layer 105 may have the same crystal structure as the free layer 104. In some embodiments, both the tunnel barrier layer 105 and the free layer 104 may have a bcc (001) crystal structure.

In various embodiments, the coherent tunneling of the free layer 104 and the pinned layer 106 can be maximized due to the high crystallinity of the tunnel barrier layer 105, thereby improving the TMR characteristic and reducing the RA value.

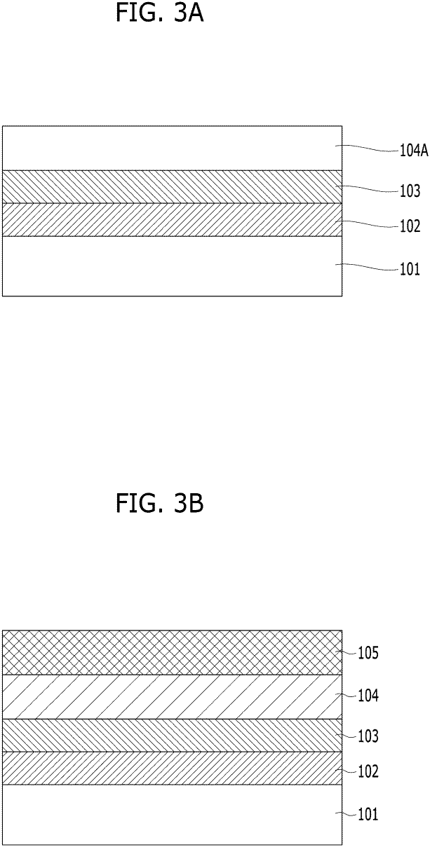

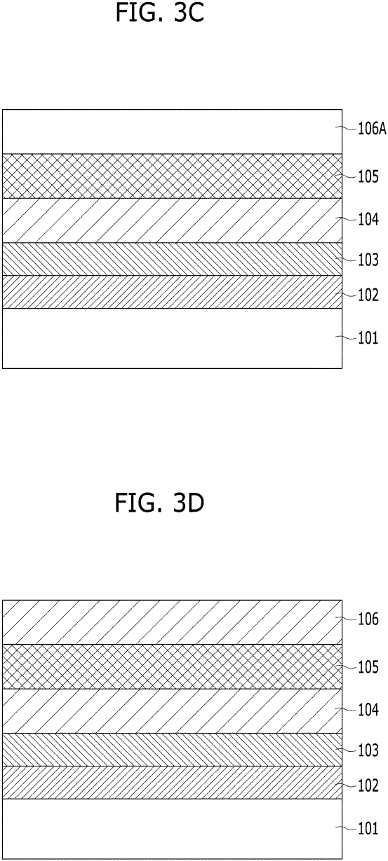

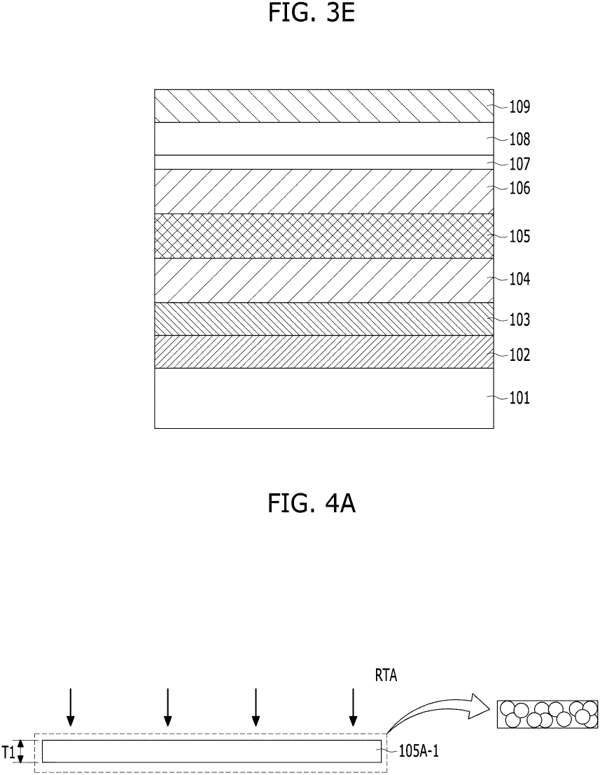

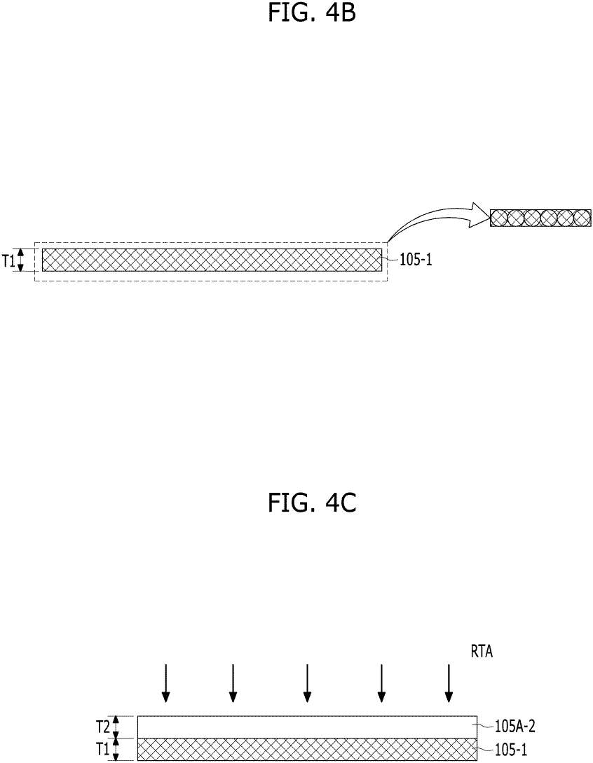

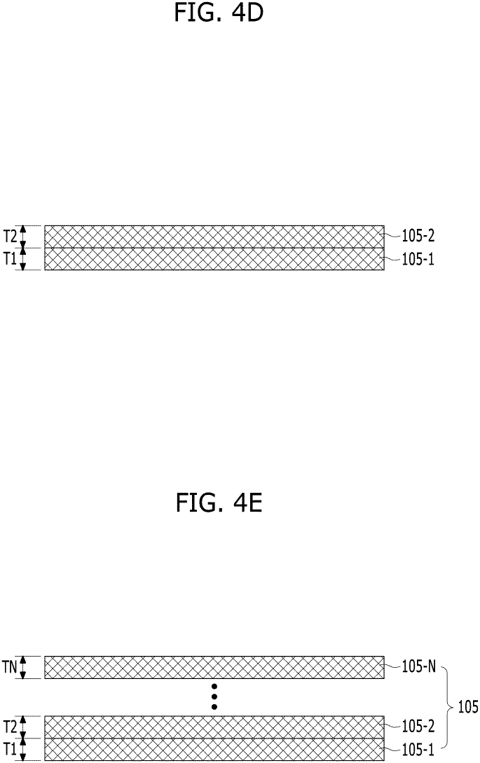

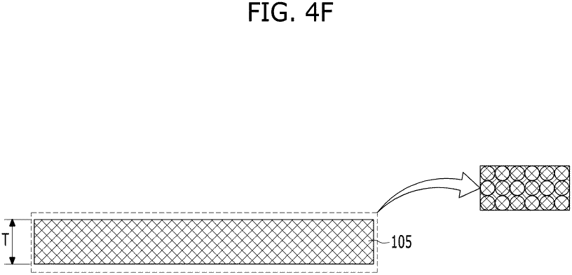

Formation of the uniform crystal structure of the tunnel barrier layer 105 will be described in detail with reference to FIGS. 3A to 3E, and FIGS. 4A to 4F.

The thickness T of the tunnel barrier layer 105 may be in a range such that the RA value is 20 Ωµm² or less. As described above, when the thickness T of the tunnel barrier layer 105 is reduced, the RA value is decreased, while the TMR is decreased and the characteristic of the variable resistance element 100 may be deteriorated. Therefore, the thickness T of the tunnel barrier layer 105 may be set so that the variable resistance element 100 exhibits optimal characteristics in consideration of the low RA value and the high TMR value.

When the tunnel barrier layer 105 has a thickness T such that the RA value is greater than 20 Ωµm², the resistance becomes excessively high so that the variable resistance element 100 is difficult to operate. The lower limit of the thickness T of the tunnel barrier layer 105 may be in a range such that the characteristics of the variable resistance element 100 are not deteriorated in consideration of both the RA value and the TMR value.

The pinned layer 106 may have a pinned magnetization direction, which remains unchanged while the magnetization direction of the free layer 104 changes. The pinned layer 106 may be referred to as a reference layer. In some implementations, the magnetization direction of the pinned layer 106 may be pinned in a downward direction. In some implementations, the magnetization direction of the pinned layer 106 may be pinned in an upward direction.

The pinned layer 106 may have a single-layer or multilayer structure including a ferromagnetic material. For example, the pinned layer 106 may include an alloy based on at least one of Fe, Ni or Co, for example, an Fe—Pt alloy, an Fe—Pd alloy, a Co—Pd alloy, a Co—Pt alloy, an Fe—Ni—Pt alloy, a Co—Fe—Pt alloy, a Co—Ni—Pt alloy, or a Co—Fe—B alloy, or may include a stack of metals, such as Co/Pt, or Co/Pd or others.

If a voltage or current is applied to the variable resistance element 100, the magnetization direction of the free layer 104 may be changed by spin torque transfer. In some implementations, when the magnetization directions of the free layer 104 and the pinned layer 106 are parallel to each other, the variable resistance element 100 may be in a low resistance state, and this may indicate digital data bit “0.” Conversely, when the magnetization directions of the free layer 104 and the pinned layer 106 are anti-parallel to each other, the variable resistance element 100 may be in a high resistance state, and this may indicate a digital data bit “1.” In some implementations, the variable resistance element 100 can be configured to store data bit ‘1’ when the magnetization directions of the free layer 104 and the pinned layer 106 are parallel to each other and to store data bit ‘0’ when the magnetization directions of the free layer 104 and the pinned layer 106 are anti-parallel to each other.

The variable resistance element 100 may further include one or more layers performing various functions to improve a characteristic of the MTJ structure. For example, the variable resistance element 100 may further include at least one of a buffer layer 102, an under layer 103, a spacer layer 107, a magnetic correction layer 108 and a capping layer 109.

The buffer layer 102 may be disposed below the under layer 103 to facilitate crystal growth of the under layer 103, thus improving perpendicular magnetic crystalline anisotropy of the free layer 104. The buffer layer 102 may have a single-layer or a multilayer structure including for example a metal, a metal alloy, a metal nitride, or a metal oxide, or a combination thereof. Moreover, the buffer layer 102 may be formed of or include for example a material compatible with a bottom electrode in order to resolve a lattice constant mismatch between the bottom electrode and the under layer 103. For example, the buffer layer 102 may include tantalum (Ta).

The under layer 103 may be disposed under the free layer 104 and serve to improve perpendicular magnetic crystalline anisotropy of the free layer 104. The under layer 103 may have a single-layer or multilayer structure including for example a metal, a metal alloy, a metal nitride, or a metal oxide, or a combination thereof. In some embodiments, the under layer 103 may include a single-layer or multilayer structure including a metal nitride. For example, the under layer 103 may include for example one or more of TaN, AIN, SiN, TiN, VN, CrN, GaN, GeN, ZrN, NbN, MoN, or HfN.

In the embodiments, intermixing or diffusion of atoms between the buffer layer 102 and under layer 103, and the free layer 104 may be prevented or minimized. Conventionally, a high-temperature and a long-time thermal treatment may be required to crystallize the layers included in the MTJ, and the thermal treatment may also affect the buffer layer 102 and the under layer 103 disposed below the MTJ. As a result, metal atoms in the buffer layer 102 and the under layer 103 may be diffused into the free layer 104, and metal atoms in the free layer 104 may be diffused into the buffer layer 102 and the under layer 103. However, in various embodiments, it is possible to minimize an amount of heat exposure to the buffer layer 102 and the under layer 103 during the thermal treatment by employing specific thermal treatment conditions (as detailed below). Therefore, intermixing or diffusion of atoms between the buffer layer 102 and under layer 103, and the free layer 104 may be prevented or minimized. Thus, the buffer layer 102, the under layer 103 and the free layer 104 may have a uniform crystal structure and a uniform composition, thereby minimizing deterioration of characteristics of the variable resistance element 100. Prevention of intermixing or diffusion of atoms between the buffer layer 102 and the under layer 103, and the free layer 104 by the specific thermal treatment will be described in detail with reference to FIGS. 3A to 3E and FIGS. 4A to 4F.

The spacer layer 107 may be interposed between the magnetic correction layer 108 and the pinned layer 106, and the spacer layer 107 may function as a buffer between the magnetic correction layer 108 and the pinned layer 106. The spacer layer 107 may be used to improve characteristics of the magnetic correction layer 108. The spacer layer 107 may include for example a noble metal such as ruthenium (Ru).

The magnetic correction layer 108 may be used to offset the effect of a stray magnetic field produced by the pinned layer 106. In this case, the effect of the stray magnetic field of the pinned layer 106 can decrease, and thus a biased magnetic field in the free layer 104 can decrease. The magnetic correction layer 108 may have a magnetization direction anti-parallel to the magnetization direction of the pinned layer 106. In the implementation, when the pinned layer 106 has a downward magnetization direction, the magnetic correction layer 108 may have an upward magnetization direction. Conversely, when the pinned layer 106 has an upward magnetization direction, the magnetic correction layer 108 may have a downward magnetization direction. The magnetic correction layer 108 may be exchange coupled with the pinned layer 106 via the spacer layer 107 to form a synthetic anti-ferromagnet (SAF) structure. The magnetic correction layer 108 may have a single-layer or multilayer structure including a ferromagnetic material.

In one embodiment, the magnetic correction layer 108 is located above the pinned layer 106, but the magnetic correction layer 108 may disposed at a different location. For example, the magnetic correction layer 108 may be located above, below, or next to the MTJ structure while the magnetic correction layer 108 is patterned separately from the MTJ structure.

The capping layer 109 may be used to protect the variable resistance element 100 and/or function as a hard mask for patterning the variable resistance element 100. In some implementations, the capping layer 109 may include various conductive materials such as a metal. In some implementations, the capping layer 109 may include for example a metallic material having almost none or a small number of pin holes, and the capping layer 109 may have a high resistance to wet and/or dry etching. In some implementations, the capping layer 109 may include for example a metal, a nitride, or an oxide, or a combination thereof. For example, the capping layer 109 may include a noble metal such as ruthenium (Ru).

The capping layer 109 may have a single-layer or multilayer structure. In some implementations, the capping layer 109 may have a multilayer structure including an oxide, or a metal, or a combination thereof. For example, the capping layer 109 may have a multilayer structure of an oxide layer, a first metal layer and a second metal layer.

A material layer for resolving the lattice structure differences and the lattice constant mismatch between the pinned layer 106 and the magnetic correction layer 108 may be interposed between the pinned layer 106 and the magnetic correction layer 108. For example, this material layer may be amorphous and may include a metal, a metal nitride, or metal oxide.

The variable resistance element 100 according to the above-described embodiments may improve the TMR characteristic and the RA value by the tunnel barrier layer 105 having a uniform crystal structure with minimized crystal defects. Further, according to the variable resistance element 100, since intermixing or diffusion of atoms between the buffer layer 102 and the under layer 103, and the free layer 104 can be prevented or minimized, each layer may have a uniform structure and a uniform composition, thereby preventing deterioration of the characteristics of the variable resistance element 100.

An example of a method for forming a semiconductor device in accordance with one embodiment of the present invention will be described with reference to FIGS. 3A to 3E. The detailed description of the variable resistance element has been described in the embodiment shown in FIG. 2.

FIGS. 3A to 3E are cross-sectional views illustrating an example of a method for forming a semiconductor device in accordance with one embodiment of the present invention.

Referring to FIG. 3A, a buffer layer 102 and an under layer 103 may be sequentially formed over a substrate 101 where a predetermined structure is formed.

The substrate 101 may include a semiconductor substrate. The substrate 101 may be formed of a silicon-containing material. The substrate 101 may include for example silicon, monocrystalline silicon, polysilicon, amorphous silicon, silicon germanium, monocrystalline silicon germanium, polycrystalline silicon germanium, carbon-doped silicon, combinations thereof or multi-layers thereof. The substrate 101 may include another semiconductor material, such as germanium. The substrate 101 may include a III/V-group semiconductor substrate, for example, a chemical compound semiconductor substrate such as gallium arsenide (GaAs). The substrate 101 may include a Silicon-On-Insulator (SOI) substrate.

The predetermined structure formed on the substrate 101 may include a switching element, a contact plug, or the like. The switching element may be connected to the variable resistance element (see the reference numeral 100 of FIG. 2 and serve to control the application of a bias to the variable resistance element 100. The switching element may include one or more transistors, diodes, or a combination of transistors and diodes. The switching element may be electrically connected to the contact plug at a portion of the switching element and to a conductive line, e.g., a source line, at another portion of the switching element.

As shown in FIG. 3A, a material layer 104A for forming a free layer may be formed over the under layer 103.

The material layer 104A may be a layer which is converted into the free layer 104 in FIG. 3B by crystallization. The material layer 104A may be amorphous.

Referring to FIG. 3B, the material layer 104A may be crystallized to form the free layer 104. A tunnel barrier layer 105 may be formed over the free layer 104.

In various embodiments, the tunnel barrier layer 105 may be formed by repeating a process of forming a unit material layer having a thin thickness and then crystallizing the layer by performing rapid thermal annealing (RTA) N times.

The formation of the tunnel barrier layer 105 will be described in detail with reference to FIGS. 4A to 4F.

Referring to FIG. 4A, a first material layer 105A-1 may be formed over the material layer 104A.

The first material layer 105A-1 may be a unit material layer for forming the tunnel barrier layer 105 and includes an insulating oxide such as for example MgO, CaO, SrO, TiO, VO, NbO, Al₂O₃, TiO₂, Ta₂O₅, RuO₂, B₂O₃, or the like.

The first material layer 105A-1 may be amorphous.

In some embodiments, a thickness T1 of the first material layer 105A-1 may be in a range of two monolayers or less. The thickness T1 of the first material layer 105A-1 may be preferably thin enough to form a sufficiently uniform crystal structure without crystallization defects by the RTA process. When the first material layer 105A-1 has a thickness greater than two monolayers, crystallization defects may occur during the crystallization and thus the first material layer 105A-1 may have a non-uniform crystal structure.

Then, the RTA process may be performed on the first material layer 105A-1.

In various embodiments, crystallization of the layers included in the MTJ may be effectively achieved by the RTA process in which heat treatment is performed within a relatively short time, as compared to the conventional high-temperature and long-time thermal treatment used for crystallization of the layers included in a conventional MTJ.

In some embodiments of the present invention, the RTA process may be performed at a temperature of 600° C. or less. The temperature of the RTA process may be selected in consideration of both aspects of crystallization of the first material layer 105A-1 and deterioration of characteristics of the variable resistance element 100. When the RTA process is performed at a temperature greater than 600° C., the crystallinity of a first sub layer (see, the reference numeral 105-1 of FIG. 4B) may be improved, while the layers disposed below the first material layer 105A-1 may be affected, thereby deteriorating characteristics of the layers. When the RTA process is performed at an excessively low temperature, sufficient energy required for crystallization of the first material layer 105A-1 may not be applied, thereby deteriorating the crystallinity of the first sub layer 105-1. Therefore, the lower limit of the temperature at which the RTA process is performed may be a temperature at which the first material layer 105A-1 can be crystallized.

In some embodiments, the RTA process may be performed for 1 minute or less. Since it is important to minimize the thermal treatment time for crystallization of the first material layer 105A-1, the RTA process may be performed for a minimum time for which the first material layer 105A-1 may be crystallized. When the RTA process is performed for more than 1 minute, heat exposure to the layers disposed below the material layer 105A-1 may be increased, thereby deteriorating characteristics of the layers. The lower limit of the time for which the RTA process is performed may be a time for which the first material layer 105A-1 can be crystallized.

Referring to FIG. 4B, the first sub layer 105-1 having a very thin thickness T1 of two monolayers or less may be formed by forming the first material layer 105A-1 as the unit material layer and performing the RTA process. As defined herein, the crystalized unit material layer by the RTA process of the invention is referred to herein as “individually crystalized.” An individually crystallized material layer does not have materials from adjacent material layers diffused into or intermixed with the individually crystallized material layer.

Since the first material layer 105A-1 may be formed to have the relatively thin thickness T1 of two monolayers or less and the thermal treatment may be performed for a very short time by the RTA process, the first sub layer 105-1 can have a uniform crystal structure without crystallization defects.

Referring to FIG. 4C, a second material layer 105A-2 may be formed over the first sub layer 105-1 and an RTA process may be performed.

The second material layer 105A-2 may include the same material as the first material layer 105A-1. In some embodiments, the second material layer 105A-2 may include an insulating oxide such as for example MgO, CaO, SrO, TiO, VO, NbO, Al₂O₃, TiO₂, Ta₂O₅, RuO₂, B₂O₃, or the like.

The second material layer 105A-2 may have a thickness T2 of two monolayers or less. The thickness T2 of the second material layer 105A-2 may be the same as or different from the thickness T1 of the first material layer 105A-1.

Conditions of the RTA process applied to the second material layer 105A-2 may be within the range described for the RTA process applied to the first material layer 105A-1. The conditions of the RTA process for the second material layer 105A-2 may be the same as or different from the conditions of the RTA process for the first material layer 105A-1.

Referring to FIG. 4D, a second sub layer 105-2 having a relatively thin thickness T2 of two monolayers or less may be formed over the first sub layer 105-1 by forming the second material layer 105A-2 and performing the RTA process.

Since the second sub layer 105-2 may be formed to have the thin thickness T2 of two monolayers or less and the thermal treatment may be performed for a relatively short time by the RTA process as compared to a conventional thermal anneal, the second sub layer 105-2 can be effectively crystalized to have a uniform crystal structure without crystallization defects.

In FIG. 4D, an interface exists between the first sub layer 105-1 and the second sub layer 105-2. However, in another embodiment, the interface may not be clearly present between the first sub layer 105-1 and the second sub layer 105-2 and the first sub layer 105-1 and the second sub layer 105-2 may exist in a fused form.

Referring to FIG. 4E, the first sub layer 105-1, the second sub layer 105-2 ...., an Nth sub layer 105-N may be formed by performing a unit cycle consisting of forming the unit material layer and performing the RTA process N times

The first sub layer 105-1, the second sub layer 105-2 ...., the Nth sub layer 105-N may form the tunnel barrier layer 105. In some embodiments, an interface may exist between the sub layers. In some embodiments, the interface may not be clearly present between the sub layers and the sub layers may exist in a fused form.

The sum of the thicknesses of sub layers (T1+T2+....+TN) may correspond to the thickness T of the tunnel barrier layer 105.

Referring to FIG. 4F, the tunnel barrier layer 105 having a uniform crystal structure may be formed by the method.

The thickness T of the tunnel barrier layer 105 may be in a range such that the RA value is 20 Ωµm² or less.

Similar to that shown in FIGS. 4A to 4F, a free layer 104 may be formed by crystallizing a material layer 104A during forming the barrier layer 105. The crystallization of the material layer 104A may be achieved over the entire N times RTA processes, or during a part of the N times RTA processes.

In one embodiment, since the RTA process for the crystallization is performed for a minimum time, an amount of heat exposure to the buffer layer 102 and the under layer 103 can be reduced, thereby preventing or minimizing the effect on the buffer layer 102 and the under layer 103. Therefore, intermixing or diffusion of atoms between the buffer layer 102 and under layer 103, and the free layer 104 may be prevented so that each layer can have a uniform structure and a uniform composition. As a result, it is possible to prevent deterioration of the characteristics of the variable resistance element 100 due to the intermixing or diffusion.

Referring to FIG. 3B again, the tunnel barrier layer 105 may be formed over the free layer 104.

The tunnel barrier layer 105 may have a uniform crystal structure without crystal defects.

The free layer 104 may have a uniform crystal structure because intermixing or diffusion of atoms between the free layer 104, and the buffer layer 102 and the under layer 103 can be prevented.

In some embodiments, the tunnel barrier layer 105 may have the same crystal structure as the free layer 104. In some embodiments, the tunnel barrier layer 105 and the free layer 104 may have a bcc (001) crystal structure.

Referring to FIG. 3C, a material layer 106A for forming a pinned layer may be formed over the tunnel barrier layer 105.

The material layer 106A may be a layer which is converted into the pinned layer 106 (shown in FIG. 3D) by crystallization. The material layer 106A may be amorphous.

Then, the material layer 106A may be crystallized by performing an annealing process. The annealing process applied to the material layer 106A may be performed under conditions such that the material layer 106A may be crystallized and layers disposed below the material layer 106A may not be affected.

Referring to FIG. 3D, the pinned layer 106 may be formed over the tunnel barrier layer 105.

Referring to FIG. 3E, a spacer layer 107, a magnetic correction layer 108 and a capping layer 109 may be sequentially formed over the pinned layer 106.

Subsequently, a patterning process such as ion beam etching process may be performed to form the variable resistance element 100.

According to one method for fabricating the variable resistance element 100 as described above, the tunnel barrier layer 105 may be formed by repeating forming a unit material layer having a thin thickness of two monolayers or less and performing an RTA process. Therefore, it is possible to improve the TMR characteristic and reduce the RA value at the same time. Moreover, heat exposure to the layers disposed below the tunnel barrier layer 105 can be reduced or minimized during the thermal treatment so that intermixing or diffusion of atoms between the buffer layer 102 and under layer 103, and the free layer 104 can be prevented. Accordingly, it is possible to reduce or minimize deterioration of the layers included in the variable resistance element 100.

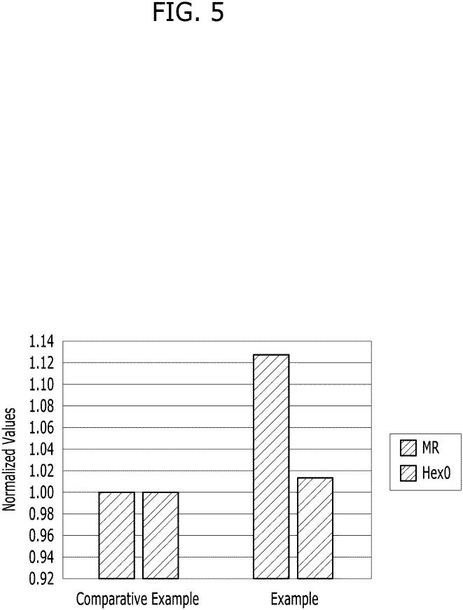

One effect according to embodiments of the present invention will be described in detail with reference to FIG. 5.

FIG. 5 is a graph illustrating magnetoresistance (MR) and exchange coupling field (Hex) characteristics of variable resistance elements in accordance with one embodiment of the present invention and comparative examples.

In FIG. 5, “Example” represents a variable resistance element formed by the methods using the RTA process shown in FIGS. 3A to 3E and FIGS. 4A to 4F, and “Comparative Example” represents a variable resistance element formed by the conventional method of forming layers included in the variable resistance element and crystallizing the layers by performing a high-temperature and long-time thermal treatment in the furnace instead of an RTA process.

As shown in FIG. 5, in case of the Example, the Hex0 characteristic is exhibited to the same degree as Comparative Example, while the MR characteristic is improved by about 13% compared to the Comparative Example. That is, according to various embodiments, it is possible to increase the crystallinity of the tunnel barrier layer and prevent intermixing or diffusion of atoms between the free layer and the layers disposed below the free layer through forming the tunnel barrier layer by repeating forming the thin unit layer and performing a short-time RTA process instead of the conventional high-temperature and long-time thermal treatment. As a result, the characteristics of the variable resistance element can be improved.

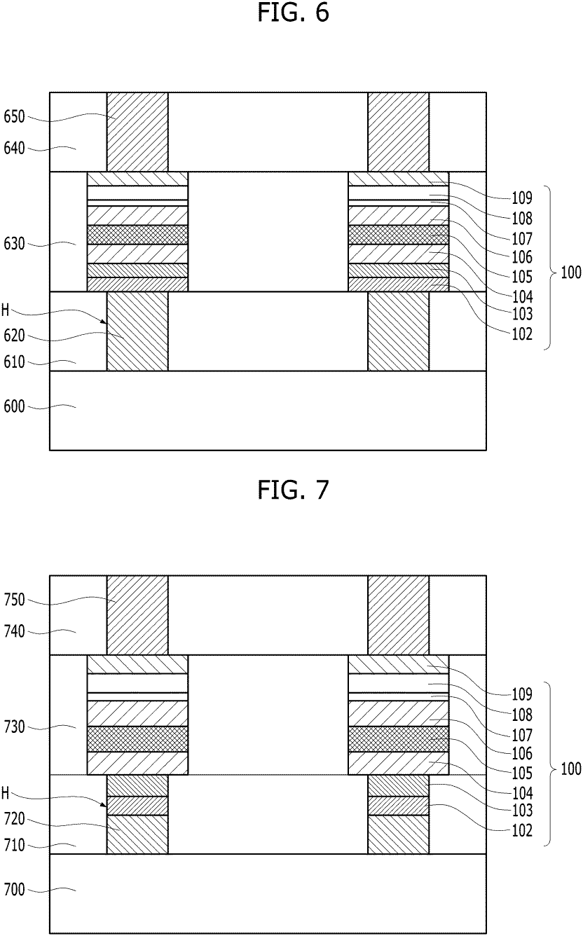

A semiconductor memory device as disclosed in this document may include a cell array of variable resistance elements 100. The semiconductor memory may further include various components such as lines, elements, etc. to drive or control each of the variable resistance elements 100. An example of this is described with reference to FIGS. 6 and 7.

FIG. 6 is a cross-sectional view of a semiconductor device showing a structure made based on some embodiments of the technology disclosed above.

Referring to FIG. 6, a semiconductor device according to one embodiment may include a substrate 600, lower contacts 620 formed over the substrate 600, corresponding variable resistance elements 100 each formed over a respective one of the lower contacts 620 and upper contacts 650 each formed over a corresponding variable resistance element 100. For each variable resistance element 100, a specific structure such as a switch or switching circuit/element, for example, a transistor, for controlling an access to a particular variable resistance element 100 may be provided over the substrate 600 to control the variable resistance element 100, where the switch can be turned on to select the variable resistance element 100 or turned off to de-select the variable resistance element 100. Each lower contact 620 may be disposed over the substrate 600, and couple a lower end of a corresponding variable resistance element 100 to a respective portion of the substrate 600, for example, a drain of the transistor as the switching circuit for the variable resistance element 100. Each upper contact 650 may be disposed over a corresponding variable resistance element 100, and couple an upper end of the variable resistance element 100 to a certain line, for example, a bit line. In FIG. 6, two variable resistance elements 100 are shown as examples of the elements in an array of variable resistance elements 100 but the number of the variable resistance elements 100 may differ.

A method for making the device may include providing the substrate 600 in which the transistor is formed. Then, a first interlayer dielectric layer 610 may be formed over the substrate 600. The lower contacts 620 may be formed by selectively etching the first interlayer dielectric layer 610 to form a plurality of spaced apart holes H, each hole H penetrating through the dielectric layer 610 to expose a corresponding portion of the substrate 600. The holes H may be filled with a conductive material. Then, the variable resistance elements 100 may be formed by forming material layers for the variable resistance elements 100 over the first interlayer dielectric layer 610 and the lower contacts 620. The material layers may be selectively etched to form the plurality of the variable resistance elements 100. Each of the variable resistance elements 100 may be positioned above a corresponding lower contact 620. The etch process for forming the variable resistance element 100 may include an ion beam etching (IBE) method which has a strong physical etching characteristic. Then, a second interlayer dielectric layer 630 may be formed to cover the space between the variable resistance elements 100 over the first dielectric layer 610. Then, a third interlayer dielectric layer 640 may be formed over the variable resistance element 100 and the second interlayer dielectric layer 630, and then upper contacts 650 passing through the third interlayer dielectric layer 640 and coupled to an upper end of corresponding variable resistance elements 100 may be formed using similar process steps as describe above for the formation of the lower contacts 620.

In the semiconductor device of FIG. 6, all layers forming the variable resistance element 100 may have sidewalls which are aligned with one another. That is because the variable resistance element 100 is formed through an etch process using a single mask.

Unlike the embodiment of FIG. 6, a part of each of the variable resistance elements 100 may be patterned separately from other parts. This process is illustrated in FIG. 7.

FIG. 7 is a cross-sectional view for describing a semiconductor device and for describing a method for fabricating the semiconductor device based on another embodiment of the present disclosure. The following descriptions will be focused on features which differ from those of FIG. 6.

Referring to FIG. 7, the semiconductor device according to one embodiment may include a variable resistance element 100 of which a part, for example, a buffer layer 102 and an under layer 103 have sidewalls that are not aligned with the sidewalls of the other layers thereof. As shown in FIG. 7, the buffer layer 102 and the under layer 103 may have sidewalls which are aligned with the sidewalls of the lower contacts 720.

The semiconductor device in FIG. 7 may be fabricated by the following processes.

First, a first interlayer dielectric layer 710 may be formed over a substrate 700, and then selectively etched to form a plurality of holes H passing through the first interlayer dielectric layer 710 to expose corresponding portions of the substrate 700. Then, the lower contacts 720 may be formed by filling only a lower portion of the holes H. For example, the lower contacts 720 may be formed through a series of processes of forming a conductive material to cover the resultant structure having the holes formed therein, and removing a part of the conductive material through an etch back process until the conductive material has a desired thickness. Then, the buffer layer 102 and the under layer 103 may be formed to fill the remaining portion of each of the holes H. For example, the buffer layer 102 may be formed by forming a material layer for forming the buffer layer 102 which covers the resultant structure in which the lower contacts 720 are formed, and then removing a part of the material layer by an etch-back process until the material layer has a desired thickness. The under layer 103 may be formed by forming a material layer for forming the under layer 103 which covers the resultant structure in which the lower contacts 720 and the buffer layer 102 are formed, and then performing a planarization process such as a CMP (Chemical Mechanical Planarization) until a top surface of the first interlayer dielectric layer 710 is exposed. Then, the remaining parts of the variable resistance element 100 may be formed by forming material layers for forming the remaining layers of the variable resistance element 100 except the buffer layer 102 and the under layer 103 over the lower contacts 720 and the first interlayer dielectric layer 710.

Subsequent processes are substantially the same as those as shown in FIG. 6.

In this embodiment, the height which needs to be etched at a time in order to form the variable resistance element 100 can be reduced, which lowers the difficulty level of the etch process.

Although in the embodiment of FIG. 7, the buffer layer 102 and the under layer 103 of the variable resistance elements 100 is buried in the corresponding holes H, other parts of the variable resistance elements 100 may also be buried as needed.

While the present invention has been described with respect to specific embodiments, it should be noted that the embodiments are for describing, not limiting, the present invention. Further, it should be noted that the present invention may be achieved in various ways through substitution, change, and modification, by those skilled in the art without departing from the scope of the present invention as set forth in the descriptions above.

What is claimed is:

1. A method for fabricating a semiconductor device comprising:
forming a first magnetic layer over a substrate;
forming a tunnel barrier layer over the first magnetic layer by repeatedly performing a unit process of forming a material layer and performing a rapid thermal annealing (RTA) process on the material layer; and
forming a second magnetic layer over the tunnel barrier layer.

2. The method of claim 1, wherein the tunnel barrier layer is formed to have a thickness such that a resistance area product (RA) value is 20 Ωµm² or less.

3. The method of claim 1, wherein the material layer is formed to have a thickness of two monolayers or less.

4. The method of claim 1, wherein the material layer is amorphous and is crystallized by the RTA process to be converted into a layer having a uniform crystal structure.

5. The method of claim 1, wherein the tunnel barrier layer is formed of an insulating oxide including at least one of MgO, CaO, SrO, TiO, VO, NbO, Al₂O₃, TiO₂, Ta₂O₅, RuO₂ and B₂O₃.

6. The method of claim 1, wherein the RTA process is performed at a temperature of 600° C. or less for 1 minute or less.

7. The method of claim 1, wherein the first magnetic layer is amorphous and is crystallized during crystallizing the material layer by the RTA process.

8. The method of claim 1, wherein the first magnetic layer and the tunnel barrier layer are formed to have the same crystal structure as each other.

9. The method of claim 1, wherein the first magnetic layer and the tunnel barrier layer are formed to have a bcc (001) crystal structure.

10. The method of claim 1, wherein a thickness of each material layer formed in each unit process is the same as or different from each other.

11. The method of claim 1, wherein a condition of the RTA process performed in each unit process is the same as or different from each other.

12. The method of claim 1, further comprising forming a buffer layer below the first magnetic layer, wherein the buffer layer has a uniform composition by suppressing intermixing or diffusion of atoms between the buffer layer and the first magnetic layer.

13. The method of claim 1, further comprising crystallizing the second magnetic layer by performing an annealing process.
